(19) United States
(12) Patent Application Publication
(10) Pub. No.: US 2023/0420963 A1
(43) Pub. Date: Dec. 28, 2023

(54) CHARGING APPARATUS, CHARGER AND SMART WEARABLE DEVICE

(71) Applicant: LUXSHARE PRECISION INDUSTRY COMPANY LIMITED, SHENZHEN (CN)

(72) Inventors: Haifa YE, SHENZHEN (CN); Xiaolong LIU, SHENZHEN (CN); Guanghong YU, SHENZHEN (CN)

(73) Assignee: LUXSHARE PRECISION INDUSTRY COMPANY LIMITED, SHENZHEN (CN)

(21) Appl. No.: 18/212,890

(22) Filed: Jun. 22, 2023

(30) Foreign Application Priority Data
Jun. 27, 2022 (CN) 202210743128.1

(51) Int. Cl. H02J 7/00; H05K 5/00; H01R 13/52; H01R 13/24; H01R 12/81; H01R 13/66

(52) U.S. Cl. CPC H02J 7/0045; H05K 5/0086; H05K 5/0069; H01R 13/521; H01R 13/24; H01R 12/81; H01R 13/6675

(57) ABSTRACT

A smart wearable device includes a housing, a charging apparatus and a charger. The charging apparatus is disposed in the housing. The charger is configured to charge the charging apparatus. The charging apparatus is mounted in the housing of the smart wearable device. The charging apparatus includes a motherboard, a battery, an adapter, and a charging contact disposed in the housing. The battery and the adapter are both electrically connected to the motherboard. The charging contact is electrically connected to the adapter and extends through the outer wall of the housing. The charging contact includes a conductive ceramic charging contact.

### CROSS-REFERENCE TO RELATED APPLICATION

This application claims priority to Chinese Patent Application No. 202210743128.1 filed Jun. 27, 2022, the disclosure of which is incorporated herein by reference in its entirety.

### TECHNICAL FIELD

The present disclosure relates to the field of electronic products, for example, a charging apparatus, a charger and a smart wearable device.

### BACKGROUND

Through a smart wearable device (such as smart glasses or a smart wearable watch), people can better perceive external information and their own information. The smart wearable device can process information more efficiently and can achieve a seamless communication among people under the assistance of a computer, a network or another person. Therefore, smart wearable devices are increasingly favored by the masses of users.

A current of a charger is transmitted to a battery of the smart wearable device in the related art through a charging contact to charge the battery, then the battery supplies power to the smart wearable device. Most charging contacts in the related art are made of platinum-plated copper. However, the surface layer of the charging contact is easy to fall off, causing a poor conductivity.

### SUMMARY

The present disclosure provides a charging apparatus and a charger.

The present disclosure also provides a smart wearable device. The preceding charging apparatus and charger are disposed in the smart wearable device.

An embodiment of the present disclosure provides a charging apparatus. The charging apparatus is mounted in the housing of a smart wearable device and includes a motherboard, a battery, an adapter, and a charging contact disposed in the housing. The battery and the adapter are both electrically connected to the motherboard. The charging contact is conductively connected to the adapter and extends through the outer wall of the housing. The charging contact includes a conductive ceramic charging contact.

In an embodiment of the present disclosure, the charging apparatus also includes a sealing member disposed between the charging contact and the outer wall of the housing.

In an embodiment of the present disclosure, the charging contact is provided with a sealing groove in a circumferential direction of the charging contact. The sealing member is a sealing ring disposed in the sealing groove.

In an embodiment of the present disclosure, the battery is disposed on one side of the charging contact and spaced apart from the charging contact. The adapter includes a flexible printed circuit (FPC). The FPC is disposed on one side of the battery. One end of the FPC is bent between the battery and the charging contact and is electrically connected to the charging contact.

In an embodiment of the present disclosure, the charging apparatus also includes a support member disposed between the battery and the charging contact. The one end of the FPC electrically connected to the charging contact is disposed on the side of the support member facing the charging contact.

In an embodiment of the present disclosure, the FPC is glued to the support member.

An embodiment of the present disclosure provides a charger. The charger is configured to charge the preceding charging apparatus.

In an embodiment of the present disclosure, the charger includes an insulating casing and a pin assembly. The pin assembly includes a pin body and an elastic member. A pilot hole is disposed in the insulating casing. The pin body slidably extends through the pilot hole. One end of the pin body protrudes from the insulating casing. The other end of the pin body is connected to the elastic member. The end of the elastic member facing away from the pin body is stopped in the pilot hole.

In an embodiment of the present disclosure, the pilot hole is a stepped hole. The diameter of the pilot hole facing an insertion end of the insulating casing is greater than the diameter of the pilot hole facing away from the insertion end of the insulating casing. The outer wall of the pin body is provided with a boss. The boss is capable of abutting a step surface in the stepped hole to stop the pin body.

An embodiment of the present disclosure provides a smart wearable device including a housing. The smart wearable device also includes the preceding charging apparatus and charger. The charging apparatus is disposed in the housing.

### BRIEF DESCRIPTION OF DRAWINGS

FIG. 1 is an exploded view of a charging apparatus, a charger and a partial housing of a smart wearable device according to an embodiment of the present disclosure.

FIG. 2 is a perspective view of a charging apparatus and a partial housing according to an embodiment of the present disclosure.

FIG. 3 is a perspective view of a charging apparatus according to an embodiment of the present disclosure.

### REFERENCE LIST

1 housing
12 outer wall of the housing
2 charging apparatus
21 battery
22 adapter
23 charging contact
231 sealing groove
24 sealing member
25 support member
26 motherboard
3 charger
31 insulating casing
311 pilot hole
32 pin assembly
321 pin body of the pin assembly
3211 outer wall of the pin body of the pin assembly
32111 boss of the outer wall of the pin body of the pin assembly
322 elastic member

### DETAILED DESCRIPTION

In the description of the present disclosure, it is to be noted that orientations or position relations indicated by terms such as “center”, “upper”, “lower”, “left”, “right”, “vertical”, “horizontal”, “in”, and “out” are based on the drawings. These orientations or position relations are intended only to facilitate and simplify the description of the present disclosure and not to indicate or imply that a device or element referred to must have such particular orientations or must be configured or operated in such particular orientations. Thus, these orientations or position relations are not to be construed as limiting the present disclosure. Moreover, terms such as “first” and “second” are used only for the purpose of description and are not to be construed as indicating or implying relative importance. For example, the terms “first position” and “second position” are two different positions.

Unless otherwise expressly specified and limited, terms “mounted”, “joined”, “connected”, and “fixed” are to be understood in a broad sense. For example, the term “connected” may refer to “securely connected”, “detachably connected”, may refer to “mechanically connected” or “electrically connected”, or may refer to “connected directly”, “connected indirectly through an intermediary” or “connected inside two components” or “interaction relations between two components”. For those of ordinary skilled in the art, the preceding terms can be construed according to specific circumstances in the present disclosure.

Unless otherwise expressly specified and limited, when a first feature is described as “above” or “below” a second feature, the first feature and the second feature may be in direct contact or be in contact via another feature between the two features. Moreover, when the first feature is described as “on”, “above” or “over” the second feature, the first feature is right on, above, or over the second feature or the first feature is obliquely on, above, or over the second feature, or the first feature is simply at a higher level than the second feature. When the first feature is described as “under”, “below” or “underneath” the second feature, the first feature is right under, below, or underneath the second feature or the first feature is obliquely under, below, or underneath the second feature, or the first feature is simply at a lower level than the second feature.

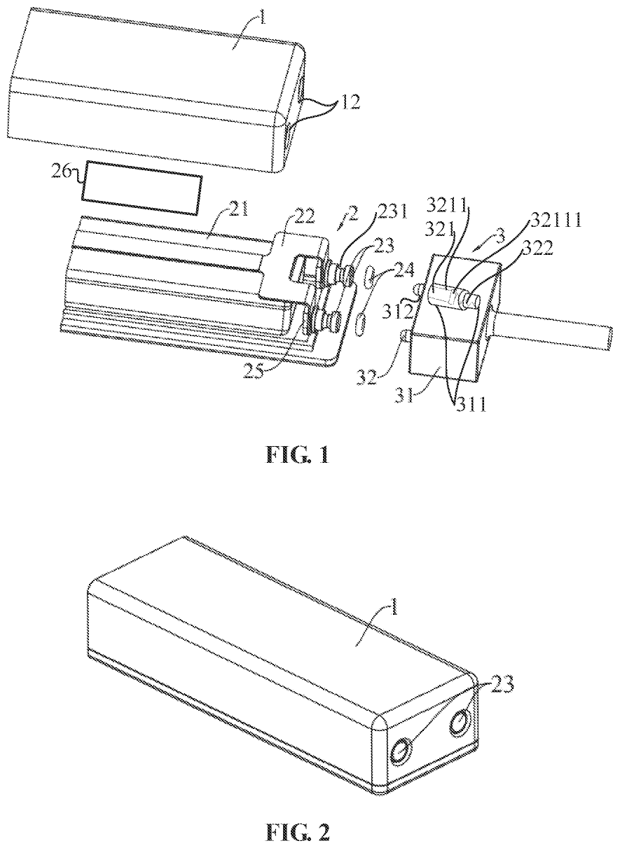

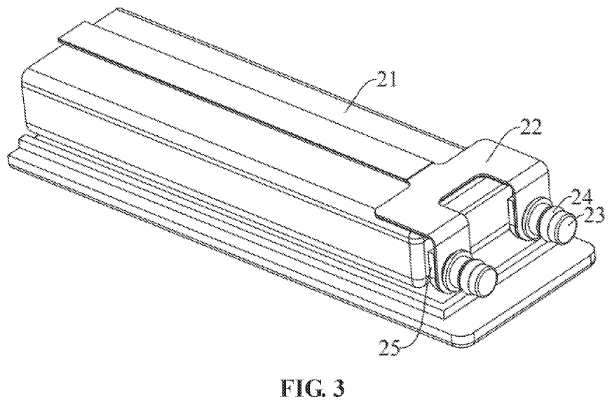

Technical solutions of the present disclosure are described hereinafter in conjunction with the FIGS. 1 to 3 and the embodiments.

In an embodiment of the present disclosure, this embodiment provides a smart wearable device. The smart wearable device includes a housing 1, a charging apparatus and a charger 3. The charging apparatus is disposed in the housing 1. The charger 3 is configured to charge the charging apparatus 2. The smart wearable device may be, but is not limited to, smart glasses or a smart watch. For ease of description, this embodiment is described using an example in which the smart wearable device is smart glasses. The charger 3 of the present disclosure can quickly charge the charging apparatus 2. The preceding charging apparatus 2 and charger 3 are disposed in the smart wearable device of the present disclosure so that the smart wearable device has a good charging performance, a more attractive appearance, and a longer service life.

In an embodiment of the present disclosure, as shown in FIGS. 1 to 3, the charging apparatus 2 is mounted in the housing 1 of the smart wearable device (for example, the housing 1 may be a temple of the smart glasses). The charging apparatus 2 includes a motherboard 26, a battery 21, an adapter 22, and a charging contact 23 disposed in the housing 1. For example, the charging apparatus 2 shown in FIGS. 1-3 includes two charging contacts 23. The battery 21 and the adapter 22 are both electrically connected to the motherboard 26. The connection mode between the battery 21 and the motherboard 26 and the connection mode between the adapter 22 and the motherboard 26 use a mature related technology and thus are not described in detail here. The charging contact 23 is conductively connected to the adapter 22 and extends through an outer wall 12 of the housing 1. The charging contact 23 includes a conductive ceramic charging contact 23.

In an embodiment of the present disclosure, the charger 3 is connected to the charging contact 23. Electric energy is input to the adapter 22 through the charging contact 23, then input to the motherboard 26 through the adapter 22, and then delivered to the battery 21 through the motherboard 26, thereby achieving the charging of the battery 21. In this embodiment, the charging contact 23 includes the conductive ceramic charging contact 23 so that the conductivity of the charging contact 23 can be improved, the charging contact 23 cannot be corroded, the service life can be prolonged. Moreover, the surface of the charging contact 23 is smoother, and the appearance of the charging contact is more attractive, improving the user experience.

A full resistance test is performed on the charging contact 23 in this embodiment. The test result is as follows:

| Serial | | | | | | | | | | | | |
|---|---|---|---|---|---|---|---|---|---|---|---|---|
| Number | Standard | 1 | 2 | 3 | 4 | 5 | 6 | 7 | 8 | 9 | 10 | Proportion |
| 1 | R ≤ 0.5 Ω | 0.32 | 0.45 | 0.36 | 0.46 | 0.47 | 0.46 | 0.47 | 0.42 | 0.36 | 0.46 | 32% |
| 2 | 0.5 < R ≤ 1.0 Ω | 0.789 | 0.891 | 0.915 | 0.645 | 0.68 | 0.82 | 0.78 | 0.89 | 0.94 | 0.92 | 28% |
| 3 | >1 Ω | 1.65 | 1.23 | 1.45 | 1.36 | 2.13 | 1.95 | 1.21 | 1.08 | 1.54 | 1.58 | 40% |

The charging contact 23 is mostly bonded to the housing 1 through glue, not facilitating disassembly and assembly. To solve the preceding problem, in an embodiment of the present disclosure, the charging apparatus 2 also includes a sealing member 24. The sealing member 24 is disposed between the charging contact 23 and the outer wall 12 of the housing 1. For example, the charging apparatus 2 shown in FIGS. 1 and 3 includes two sealing members 24, each sealing member 24 is disposed between a respective charging contact 23 and the outer wall 12 of the housing 1.

In an embodiment of the present disclosure, the charging contact 23 is provided with a sealing groove 231 in a circumferential direction of the charging contact 23. The sealing member 24 is a sealing ring disposed in the sealing groove 231. The sealing ring is easy to assemble and disassemble, thereby facilitating the assembly and disassembly of the charging device 2 in this embodiment.

In an embodiment of the present disclosure, the battery 21 is disposed on one side of the charging contact 23 and spaced apart from the charging contact 23. The adapter 22 includes a FPC. The FPC is disposed on one side of the battery 21. One end of the FPC is bent between the battery 21 and the charging contact 23 and is electrically connected to the charging contact 23. The one end of the FPC is bent and connected to the charging contact 23 so that it is possible to avoid connecting the charging contact 23 to the FPC through the adapter 22, thereby saving both components and space and making the overall structure of the charging apparatus 2 more compact.

In an embodiment of the present disclosure, as shown in FIG. 3, in this embodiment, the charging apparatus 2 also includes a support member 25. The support member 25 is disposed between the battery 21 and the charging contact 23. The one end of the FPC electrically connected to the charging contact 23 is disposed on the side of the support member 25 facing the charging contact 23. In this embodiment, preferably, the FPC is glued to the support member 25. It is to be understood that the support member 25 can withstand the plug force of the charging contact 23, making the charging contact 23 more stable. Meanwhile, the support member 25 can support the FPC, reducing the deformation of the FPC, and stabilizing the contact between the charging contact 23 and the FPC. For example, the charging apparatus 2 shown in FIGS. 1 and 3 includes two support members 25, each support member 25 is disposed between the battery 21 and a respective charging contact 23.

In an embodiment of the present disclosure, as shown in FIG. 1, in this embodiment, the charger 3 includes an insulating casing 31 and a pin assembly 32. For example, the charger 3 shown in FIG. 1 includes two pin assemblies 32. Each pin assembly 32 includes a pin body 321 and an elastic member 322. A pilot hole 311 is disposed in the insulating casing 31. The pin body 321 slidably extends through the pilot hole 311. One end of the pin body 321 protrudes from the insulating casing 31. Another end of the pin body 321 is connected to the elastic member 322. The end of the elastic member 322 facing away from the pin body 321 is stopped in the pilot hole 311. In some optional embodiments, the elastic member 322 is a spring. Certainly, those skilled in the art may also configure the elastic member 322 to be in another form. The specific form of the elastic member 322 is not limited herein. After the pin body 321 abuts the charging contact 23, the charging contact 23 poses a reverse force on the pin body 321, and the elastic member 322 is compressed to pose an elastic force on the pin body 321. In this manner, the pin body 321 can be in better contact with the charging contact 23, improving the stability of the charging process.

In an embodiment of the present disclosure, the pilot hole 311 is a stepped hole. The diameter of the pilot hole 311 facing an insertion end 312 of the insulating casing 31 is greater than the diameter of the pilot hole 311 facing away from the insertion end 312 of the insulating casing 31. The outer wall 3211 of the pin body 321 is provided with a boss 32111. The boss 32111 is capable of abutting a step surface in the stepped hole 311 to stop the pin body 321. The step in the stepped hole and the boss 32111 can stop the pin body 321 so as to prevent the pin body 321 from disengaging from the insulating casing 31.

What is claimed is:

1. A charging apparatus, the apparatus being mounted in a housing of a smart wearable device and comprising a motherboard, a battery, an adapter, and a charging contact disposed in the housing, wherein
the battery and the adapter are both electrically connected to the motherboard,
the charging contact is electrically connected to the adapter, the charging contact extends through an outer wall of the housing, and the charging contact comprises a conductive ceramic charging contact.

2. The charging apparatus according to claim 1, further comprising: a sealing member disposed between the charging contact and the outer wall of the housing.

3. The charging apparatus according to claim 2, wherein the charging contact is provided with a sealing groove in a circumferential direction of the charging contact, and the sealing member is a sealing ring disposed in the sealing groove.

4. The charging apparatus according to claim 1, wherein the battery is disposed on one side of the charging contact and spaced apart from the charging contact, and the adapter comprises a flexible printed circuit (FPC), wherein the FPC is disposed on one side of the battery, and one end of the FPC is bent between the battery and the charging contact and is electrically connected to the charging contact.

5. The charging apparatus according to claim 4, further comprising a support member disposed between the battery and the charging contact, wherein the one end of the FPC electrically connected to the charging contact is disposed on a side of the support member facing the charging contact.

6. The charging apparatus according to claim 5, wherein the FPC is glued to the support member.

7. A charger, configured to charge a charging apparatus, wherein the charging apparatus is mounted in a housing of a smart wearable device and comprises a motherboard, a battery, an adapter, and a charging contact disposed in the housing, the battery and the adapter are both electrically connected to the motherboard, the charging contact is electrically connected to the adapter, the charging contact extends through an outer wall of the housing, and the charging contact comprises a conductive ceramic charging contact.

8. The charger according to claim 7, comprising an insulating casing and a pin assembly, wherein the pin assembly comprises a pin body and an elastic member, a pilot hole is disposed in the insulating casing, the pin body slidably extends through the pilot hole, one end of the pin body protrudes from the insulating casing, another end of the pin body is connected to the elastic member, and an end of the elastic member facing away from the pin body is stopped in the pilot hole.

9. The charger according to claim 8, wherein the pilot hole is a stepped hole, a diameter of the pilot hole facing an insertion end of the insulating casing is greater than a diameter of the pilot hole facing away from the insertion end of the insulating casing, an outer wall of the pin body is provided with a boss, and the boss is capable of abutting a step surface in the stepped hole to stop the pin body.

10. The charger according to claim 7, wherein the charging apparatus further comprises: a sealing member disposed between the charging contact and the outer wall of the housing.

11. The charger according to claim 10, wherein the charging contact is provided with a sealing groove in a circumferential direction of the charging contact, and the sealing member is a sealing ring disposed in the sealing groove.

12. The charger according to claim 7, wherein the battery is disposed on one side of the charging contact and spaced apart from the charging contact, the adapter comprises a flexible printed circuit, FPC, the FPC is disposed on one side of the battery, and one end of the FPC is bent between the battery and the charging contact and is electrically connected to the charging contact.

13. The charger according to claim 12, wherein the charging apparatus further comprises a support member disposed between the battery and the charging contact; and
the one end of the FPC electrically connected to the charging contact is disposed on a side of the support member facing the charging contact.

14. The charger according to claim 13, wherein the FPC is glued to the support member.

15. A smart wearable device, comprising a housing, a charging apparatus, and a charger, wherein
the charging apparatus is mounted in the housing of a smart wearable device and comprises a motherboard, a battery, an adapter, and a charging contact disposed in the housing, the battery and the adapter are both electrically connected to the motherboard, the charging contact is electrically connected to the adapter, the charging contact extends through an outer wall of the housing, the charging contact comprises a conductive ceramic charging contact, the charger is configured to charge the charging apparatus, and the charging apparatus is disposed in the housing.

16. The smart wearable device according to claim 15, wherein the charging apparatus further comprises: a sealing member disposed between the charging contact and the outer wall of the housing.

17. The smart wearable device according to claim 16, wherein the charging contact is provided with a sealing groove in a circumferential direction of the charging contact, and the sealing member is a sealing ring disposed in the sealing groove.

18. The smart wearable device according to claim 15, wherein the battery is disposed on one side of the charging contact and spaced apart from the charging contact, the adapter comprises a flexible printed circuit, FPC, the FPC is disposed on one side of the battery, and one end of the FPC is bent between the battery and the charging contact and is electrically connected to the charging contact.

19. The smart wearable device according to claim 15, wherein the charger comprises an insulating casing and a pin assembly, the pin assembly comprises a pin body and an elastic member, a pilot hole is disposed in the insulating casing, the pin body slidably extends through the pilot hole, one end of the pin body protrudes from the insulating casing, another end of the pin body is connected to the elastic member, and an end of the elastic member facing away from the pin body is stopped in the pilot hole.

20. The smart wearable device according to claim 19, wherein the pilot hole is a stepped hole, a diameter of the pilot hole facing an insertion end of the insulating casing is greater than a diameter of the pilot hole facing away from the insertion end of the insulating casing, an outer wall of the pin body is provided with a boss, and the boss is capable of abutting a step surface in the stepped hole to stop the pin body.
